(19) United States
(12) Patent Application Publication
(10) Pub. No.: US 2017/0178918 A1
(43) Pub. Date: Jun. 22, 2017

(54) POST-POLISH WAFER CLEANING

(71) Applicant: GLOBALFOUNDRIES Inc., Grand Cayman (KY)

(72) Inventor: Thomas Gyulai, Radeburg (DE)

(21) Appl. No.: 14/974,309

(22) Filed: Dec. 18, 2015

(51) Int. Cl. H01L 21/306; B24B 27/033; H01L 21/02

(52) U.S. Cl. CPC H01L 21/30625; H01L 21/02052; B24B 27/033

(57) ABSTRACT

An apparatus for semiconductor wafer treatment is provided including a polishing stage configured for polishing a surface of the semiconductor wafer, a rinse stage configured for cleaning the surface of the semiconductor wafer and a mixer connected with the rinse stage and configured for supplying a mixture of at least deionized water and an inert gas to the rinse stage.

### BACKGROUND

1. Field of the Invention

Generally, the present disclosure relates to the field of manufacturing of integrated circuits and semiconductor devices, and, more particularly, to the cleaning of semiconductor wafers after polishing.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. Miniaturization and increase of circuit densities represent ongoing demands.

Semiconductor wafers are typically fabricated with multiple copies of a desired integrated circuit design that will later be separated and made into individual chips. Wafers are commonly constructed in layers, where a portion of a circuit is created on a first level and conductive vias are made to connect up to the next level of the circuit. After each layer of the circuit is etched on the wafer, an oxide layer is put down, allowing the vias to pass through but covering the rest of the previous circuit level. Each layer of the circuit may create or add unevenness to the wafer that must be smoothed out before generating the next circuit layer.

Chemical mechanical planarization/polishing (CMP) is an established technology used to planarize the raw wafer and each layer of material added thereafter. Available CMP systems, commonly called wafer polishers, often use a rotating wafer carrier that brings the wafer into contact with a polishing pad rotating in the plane of the wafer surface to be planarized. A polishing fluid, such as a chemical polishing agent or slurry containing micro-abrasives, is applied to the polishing pad to polish the wafer. The wafer carrier then presses the wafer against the rotating polishing pad and is rotated to polish and planarize the wafer.

Following the polishing and planarization operation, the wafer carrier is lifted off of the polishing pad and retained in a conveyor that is used to transport the wafer and wafer carrier. The external surfaces of the wafer carrier and the face of the wafer are typically coated with the residual polishing fluid and the material removed from the wafer surface during the operation. Slurry and polishing pads are sources of contaminating the surface of a wafer.

Wafer cleaning after CMP is a critical issue. Insufficient wafer cleaning results in major defects, for instance, scratches, during the following processing, for example, a further polishing step of a final brush clean. These contaminants are typically removed using deionized water (DIW). For example, a head diametrical wash system comprises fixed holes that are included on the conveyor. The holes surround the upper portion of the wafer carrier when it is retained in the conveyor. The holes are piped to a DIW supply that is pressurized to spray DIW out of the holes and onto the outer surface of the wafer carrier.

However, the conventional interstation rinse does not reliably remove particles, for example, slurry particles, with particular surface tension. In view of this, the present disclosure provides a new post-polish wafer cleaning that more reliably removes contaminants from wafer surfaces as compared to the art.

### SUMMARY OF THE INVENTION

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to the cleaning of surfaces of semiconductor wafers after a polishing process, in particular, after a CMP step.

An apparatus for semiconductor wafer treatment is provided including a polishing stage configured for polishing a surface of the semiconductor wafer, a rinse stage configured for cleaning the surface of the semiconductor wafer and a mixer connected with the rinse stage and configured for supplying a mixture of at least deionized water and an inert gas to the rinse stage.

Furthermore, a method of cleaning a surface of a semiconductor wafer is provided including moving the semiconductor wafer to a rinse stage of a wafer treatment apparatus, supplying a mixture of at least deionized water (DIW) and an inert gas to the rinse stage and rinsing the surface of the semiconductor wafer with the supplied mixture in the rinse stage.

Further, a post-polishing cleaning method for cleaning a surface of a polished semiconductor wafer is provided including rinsing the surface of the polished semiconductor wafer with a rinsing fluid comprising deionized water (DIW) and a pressurized inert gas.

In all of the above-mentioned examples, the mixture may comprise additional components, for example, CO₂, and the inert gas may comprise or consist of pressurized N₂. According to particular examples, the mixture may consist of the DIW and the inert gas. The semiconductor wafer may be an SOI wafer with a semiconductor substrate, a buried oxide layer formed on the semiconductor substrate and a semiconductor layer formed on the buried oxide layer. The semiconductor wafer may comprise FDSOI devices, such as FDSOI FETs.

### BRIEF DESCRIPTION OF THE DRAWINGS

The disclosure may be understood by reference to the following description taken in conjunction with the accompanying drawings, in which like reference numerals identify like elements, and in which:

FIG. 1 shows an apparatus comprising polishing stations and rinse stations supplied with a mixture of DIW and an inert gas; and

FIG. 2 shows a flow chart of a wafer processing including wafer cleaning by a mixture of DIW and an inert gas.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the disclosure. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, e.g., NMOS, PMOS, CMOS, etc. The techniques and technologies described herein may be utilized to fabricate MOS integrated circuit devices, including NMOS integrated circuit devices, PMOS integrated circuit devices, and CMOS integrated circuit devices.

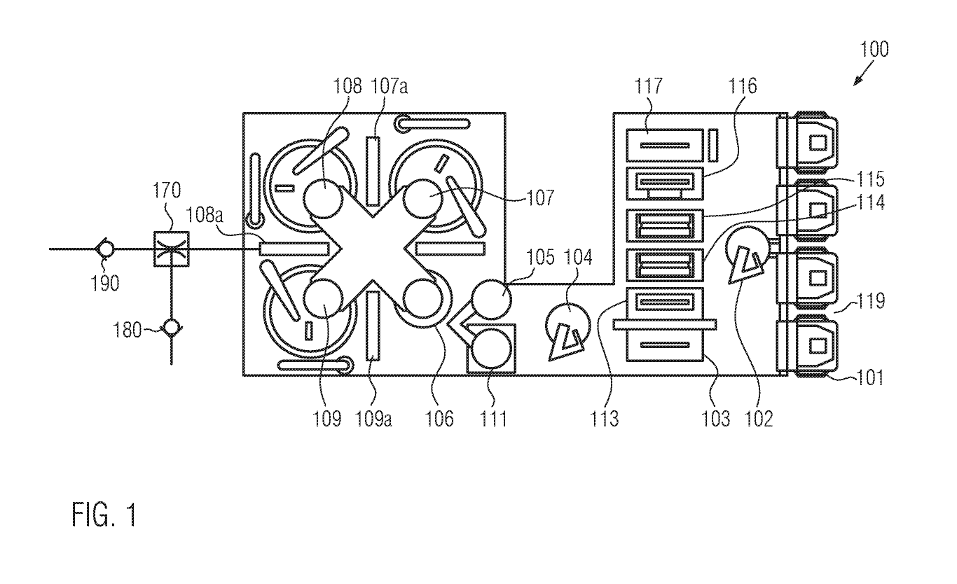

The present disclosure provides an apparatus for wafer CMP and cleaning. An example of such an apparatus 100 is illustrated in FIG. 1. The apparatus 100 of FIG. 1 comprises a load port 101 for introduction of a wafer to be processed in the apparatus 100. A robot (wafer handler) 102 is provided for wafer transport in the apparatus 100. The wafer is transferred by the robot 102 to a pass through means (dry to wet area) 103. On the other side of the pass through means 103, another robot (wet robot) 104 is provided for further transport of the wafer to input station 105 and head load/unload station 106.

The apparatus 100 furthermore comprises first 107, second 108 and third 109 polishing stages (stations) for wafer polishing. The polishing stages 107, 108, 109 may, for example, be CMP stations. The first polishing stage 107 may comprise a first polishing pad and a first wafer carrier, the second polishing stage 108 may comprise a second polishing pad and a second wafer carrier and the third polishing stage 109 may comprise a third polishing pad and a third wafer carrier. The wafer carriers may be configured for serially transferring wafers between the polishing stages 107, 108 and 109. The polishing stages 107, 108 and 109 may be configured to remove one or more layers (not shown) disposed on the wafer to be processed. The one or more layers, for example, may comprise one or more of a barrier layer, dielectric layer (e.g., a layer of oxide or nitride), metal layer (e.g., a layer of copper, aluminum, tantalum, titanium and/or tungsten), or any other layer formed on the wafer. The apparatus 100 may comprise additional polishing stages and one of the additional polishing stages may comprise a buffing pad for buffing or surface conditioning of a wafer treated in a previous polishing stage.

The apparatus 100 furthermore may comprise a first post polish clean station (first rinse stage) 107a downstream of the first polishing stage 107, a second post polish clean station (second rinse stage) 108a downstream of the second polishing stage 108 and a third post polish clean station (third rinse stage) 109a downstream of the third polishing stage 109. After a polishing step in one of the polishing stages 107, 108 and 109, a rinsing step in one of the post polish clean stations 107a, 108a and 109a, respectively, may be performed. For example, in the first polishing stage 107, a first layer of the wafer is planarized or removed and the resulting wafer is rinsed in the first post polish clean station 107a and subsequently the wafer is treated in the second polishing stage 108, etc.

The post polish clean stations 107a, 108a, 109a may be fed by a mixer 170. Deionized water (DIW) is supplied to the mixer 170 from a DIW supply 190 and an inert gas is supplied to the mixer 170 from an inert gas supply 180. The DIW may have a pH value of about 6. The mixer 170 may be a venturi mixer. A venturi mixer allows for efficient mixing of a liquid and a gas, in this case, the DIW and the inert gas. Mixing rates may be accurately tuned. The DIW and the inert gas are mixed in the mixer 170 and supplied to the post polish clean stations 107a, 108a, 109a in order to carry out wafer cleaning by a mixture of the DIW and the inert gas. The inert gas may comprise or consist of nitrogen or a rare gas. Whereas the DIW may be supplied to the mixer 170 at a relatively low pressure, the inert gas may be supplied at a relatively high pressure. The resulting mixture may be considered as a high-pressure rinsing fluid. The DIW is accelerated by the inert gas as compared to conventional rinsing. Typical pressures involved are 130-280 kPa with a gas flow rate of approximately 10-30 l/min. Other components, for example, CO₂, may be included in the rinsing fluid.

Contrary to the art, the rinsing is not only performed by rinsing DIW, but the mixture of DIW and an inert gas. Thereby, even heavily fixed contaminating particles, for example, benzotriazole (BTA) particles stemming from a polishing slurry, may be removed from a wafer surface directly after a polishing process was performed. The post-polishing rinsing with DIW and an inert gas allows for removing metallic and ionic particles. By the improved wafer cleaning, cross contamination can be significantly reduced as compared to the art. Most importantly, scratches caused by contaminants on a wafer surface in a subsequently performed polishing step or after transfer of the wafer to the brush clean station in a subsequently performed brush cleaning may be avoided.

It should be noted that the mixture of DIW and inert gas may also be supplied to a buffing stage. The addition of the mixture of DIW and an inert gas may be beneficial in preventing remaining slurry particles from drying onto a wafer surface.

After treatment by one or more of the polish and post polish clean stations described above, the wafer may be transferred to a clean input station 113 of a brush clean station via the output station 111 and (wet) robot 104. Wafer clean and dry stations 114 to 117 are comprised in the apparatus for brush cleaning and drying. The wafer may be transferred by robot 102 to wafer output port 119 where the cleaned and dried wafer may leave the apparatus 100.

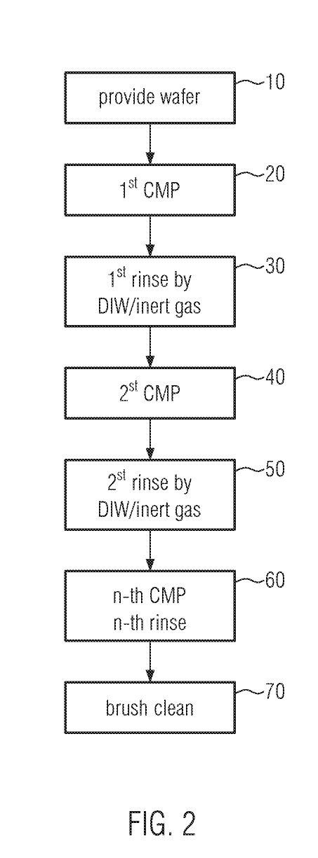

A process flow of an exemplary wafer treatment is illustrated in FIG. 2. A wafer is provided 10 that may be an SOI wafer comprising a semiconductor bulk substrate, a buried oxide layer formed on the bulk substrate and a semiconductor layer formed on the buried oxide layer. The semiconductor substrate may be a silicon substrate, in particular, a single crystal silicon substrate. Other materials may be used to form the semiconductor substrate such as, for example, germanium, silicon germanium, gallium phosphate, gallium arsenide, etc. The buried oxide layer may comprise silicon dioxide, silicon nitride or any other suitable material. The semiconductor layer may be comprised of any appropriate semiconductor material, such as silicon, silicon/germanium, silicon/carbon, other II-VI or III-V semiconductor components and the like. The semiconductor layer may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon and the like. A pattern of integrated circuits may be formed on the wafer. In particular, the wafer may comprise multiple Fully Depleted (FD) SOI devices, for example, FDSOI FETs.

The wafer is subject to a first CMP process 20. During the first CMP process, a metal or mask layer may be removed from the wafer. After completion of the first CMP process 20, a first wafer cleaning 30 is performed. The first wafer cleaning 30 comprises high-pressure rinsing of the wafer with a mixture of DIW and an inert gas, for example, an N₂ gas. After completion of the first wafer cleaning 30, a second CMP process 40 is performed, for example, for planarizing a dielectric layer. After completion of the second CMP process 40, a second wafer cleaning 50 is performed. Similar to the first wafer cleaning 30, the second wafer cleaning 50 comprises high-pressure rinsing of the wafer with a mixture of DIW and an inert gas, for example, an N₂ gas. Additional CMP and rinsing steps may be performed. In total the wafer may be subject to n CMP and rinsing steps. After completion of the n-th CMP and rinsing steps 60, the wafer is brush cleaned 70. It is noted that a third CMP process followed by a third wafer cleaning may be carried out between the step of the second wafer cleaning 50 and the step of brush cleaning 70. Due to the previously performed efficient cleaning by a high-pressure mixture of DIW and an inert gas, the generation of scratches may largely be avoided in the brush cleaning process.

In this context, the following should also be noted. Copper has become a very important material for the creation of multilevel interconnections. However, copper lines frequently show defects after conventional CMP and cleaning processing. This in turn causes problems with planarization of subsequent layers that are deposited over the copper lines since these layers may now be deposited on a surface of poor planarity. Isolated copper lines or copper lines that are adjacent to open fields are susceptible to damage. These problems may be solved or at least alleviated by the wafer cleaning making use of DIW and an inert gas as taught herein.

The overall processing of a semiconductor wafer may include forming a dielectric layer over a semiconductor substrate, etching a plurality of trenches into the dielectric layer, and forming a barrier layer over the dielectric layer and the trenches. These known processes also may include forming a copper seed layer over the barrier layer and forming a copper layer over the copper seed layer, such that a portion of the copper seed layer and a portion of the copper layer also are disposed in the trenches. In these known processes, the copper layer, the copper seed layer and the barrier layer may be removed over portions of the wafer during the first and/or second CMP processes 20 and 40 by means of a polishing pad rotating with respect to the wafer. The wafer may also rotate with respect to the rotating polishing pad. A slurry composition may be disposed on the side of the polishing pad in contact with the various layers on the wafer, wherein the slurry composition assists in polishing and/or oxidizing the layers. One polishing pad may be used to remove copper layer(s) during the first CMP process 20 and another polishing pad may be used to remove a barrier layer during the second CMP process, for example.

It should be noted that additional steps might be performed in the process flow shown in FIG. 2. For example, additional CMP and rinsing steps may be performed. For example, one or more buffing steps and drying steps may be performed. Moreover, after a wafer cleaning process making use of a rinsing fluid comprising DIW and an inert gas, megasonic treatment of the wafer may be performed. For example, a megasonic bath having an appropriate pH value further removes particles and metallic and ionic contaminants. A megasonic cleaning bath may be accomplished by filling the megasonic bath tank with a cleaning solution, such as NH₄OH, and applying megasonic power on the order of 250 watts. Quick rinsing cycles may be added before and after the megasonic cleaning bath to improve results. A megasonic rinsing bath may also be included. A megasonic rinsing bath comprises filling the tank with a rinsing solution such as DIW and applying megasonic power on the order of 250 watts.

After the megasonic bath (if one is desired), the wafer may be transferred to a scrubber for brush cleaning 70, for example, using a wet transfer. The wafer may be stored in a DIW solution while awaiting brush cleaning. The scrubber contains a box for wafer storage where wafers are constantly sprayed with DIW or other appropriate chemicals previously. The scrubber may contain a brush for scrubbing the wafer surface. Both the wafer and the brush may be rotated while a controlled pH solution, such as NH₄OH and/or DIW, is added. Other chemistries may be used in place of NH₄OH, preferably having a pH value similar to that of the slurry used during the CMP processes 20 and 40. Both the front and back sides of each wafer may be brush cleaned using different scrubbing stations. If desired, a low concentration HF spray may be used after brush cleaning to remove metal contaminants. After completion of the brush cleaning process 70, the wafer may be transferred to a spin dry station where it can be spun dry. After that, the wafer is ready for subsequent processing or testing.

As a result, an apparatus for wafer polishing and cleaning and a method of wafer cleaning after wafer polishing is provided. In particular, the herein disclosed wafer cleaning may be integrated in the 22 nm FDSOI technology.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1.-6. (canceled)

7. A method of treating a surface of a semiconductor wafer, the method comprising:
performing a first polishing, process on a first layer formed on said semiconductor wafer using a first slurry composition in a first polishing stage of a water treatment apparatus,
moving said semiconductor wafer from said first polishing stage to a rinse stage of said wafer treatment apparatus and performing a first rinsing process of said surface of said semiconductor wafer in said rinse stage using a mixture of at least deionized water (DIW) and an inert gas after performing said first polishing process;
moving said semiconductor wafer from said rinse stage to a second polishing stage of said wafer treatment apparatus and performing a second polishing process on a second layer formed on said semiconductor wafer different than said first layer using a second slurry composition after performing said first rinsing process,
moving said semiconductor wafer from said second polishing stage to said rinse stage and performing a second rinsing process of said surface of said semiconductor wafer with said mixture in said rinse stage after performing said second polishing process.

8. The method of claim 7, wherein said inert gas is pressurized nitrogen.

9. The method of claim 7, further comprising brush cleaning said surface of said semiconductor wafer after completion of said second rinsing process.

10.-13. (canceled)

14. The method of claim 7, wherein said mixture is supplied to said rinse stage by a mixer and further comprising supplying said inert gas from an inert gas supply to said mixer and supplying said DIW from a DIW supply to said mixer.

15. The method of claim 7, wherein said semiconductor wafer is an SOI wafer comprising FDSOI devices.

16. A post-polishing cleaning method for cleaning a surface of a semiconductor wafer, the method comprising:
providing a plurality of layers on said semiconductor wafer;
performing a plurality of polishing processes to remove selected ones of said plurality of layers,
rinsing said surface of said polished semiconductor wafer between each of said polishing processes with a rinsing fluid comprising deionized water (DIW) and a pressurized inert gas.

17. The method of claim 16, wherein said pressurized inert gas comprises nitrogen.

18. The method of claim 16, further comprising brush cleaning said semiconductor wafer after completing said plurality of polishing processes and said rinsing process.

19. (canceled)

20. The method of claim 16, wherein said semiconductor wafer is an SOI wafer comprising FDSOI devices.
